(19) United States
(12) Patent Application Publication
(10) Pub. No.: US 2026/0188411 A1
(43) Pub. Date: Jul. 2, 2026

(54) MEMORY SYSTEM AND A TESTING METHOD

(71) Applicant: Winbond Electronics Corp., Taichung City (TW)

(72) Inventor: Byung-Jae Lee, Hsinchu (TW)

(73) Assignee: Winbond Electronics Corp., Taichung City (TW)

(21) Appl. No.: 19/007,601

(22) Filed: Jan. 2, 2025

(51) Int. Cl. G11C 29/38

(52) U.S. Cl. CPC G11C 29/38

(57) ABSTRACT

A memory system includes an electronic device and a memory device. The memory device includes an input pad for receiving an input signal and an output pad for outputting a first output signal in a first test mode and outputting a second output signal in a second test mode. The memory device further includes memory interface which has a transceiver and a mode selecting circuit. The transceiver communicates with the electronic device, and the mode selecting circuit selects the first test mode or the second test mode. Loading from the transceiver of the memory interface and the electronic device are included in the first test mode, and the loading from the transceiver of the memory interface and the electronic device are excluded in the second test mode. The memory system may compare the first output signal and the second output signal to generate a test result.

### BACKGROUND

### Technical Field

The disclosure generally relates to testing of memory system, and more particularly relates to a memory system and a method for testing the memory system that can efficiently test the memory system without affecting normal user mode operations of the memory system.

### Description of Related Art

A memory system may have multiple chips such as a system-on-chip (SoC) device and a memory device connected to each other via embedded pins. Mutual transmission and reception between the memory device and the SoC device have become more complicated with various product specifications and different customer's demands. It is difficult to monitor interfaces of the embedded pins under various conditions such as high-speed operations, high/low voltage operations, different interface power levels, small pin cap requirements, many input/output (IOs), and tight direct-current (DC) or alternating current (AC) parameters. To test the interface of the embedded pins in the memory system, a design-for-testing (DfT) circuit can be connected directly to a memory interface of the memory device. However, the DfT circuit may adversely affect operations of the memory system, especially in high-speed and/or low-power operations of the memory system. A connection of the DfT circuit to the interface of the memory device may result in additional loading affecting pin's capacitance (Pin-Cap), negative impact on interface operation of the memory device, a potential leakage path between the memory device and SoC device, an increase of chip size.

Alternatively, package ballouts or directly probing methods may also be utilized to test the interface of the pins in the memory system. However, the package ballouts may damage a normal user mode of the memory device with additional loading, and test results can be distorted if the memory system is tested directly with probing methods. The designs of both DfT circuit and package ballouts or directly probing methods may affect chip performance and cost during mass-producing products.

It is desirable for a novel technique for testing a memory system that may effectively test the memory system and an interface of embedded pins in the memory system.

### SUMMARY

In some embodiments of the disclosure, a memory system includes an electronic device, a memory device, and a testing device. The memory device includes an input pad for receiving an input signal and an output pad for outputting a first output signal in a first test mode and outputting a second output signal in a second test mode. The memory device further includes memory interface which has a transceiver and a mode selecting circuit. The transceiver communicates with the electronic device, and the mode selecting circuit selects the first test mode or the second test mode. Loading from the transceiver of the memory interface and the electronic device are included in the first test mode, and the loading from the transceiver of the memory interface and the electronic device are excluded in the second test mode. The testing device may compare the first output signal and the second output signal to generate a test result.

In some embodiments of the disclosure, a memory system includes an electronic device and a memory device. The memory device includes an input pad for receiving an input signal and an output pad for outputting a first output signal in a first test mode and outputting a second output signal in a second test mode. The memory device may further include a memory interface that has a transceiver and a mode selecting circuit. The transceiver may communicate with the electronic device, and the mode selecting circuit may select the first test mode or the second test mode. Loading from the transceiver of the memory interface and the electronic device are included in the first test mode, and the loading of the transceiver of the memory interface and the electronic device are excluded in the second test mode. The memory device may further include a signal comparator that compares the first output signal and the second output signal to generate a test result.

In some embodiments of the disclosure, a method of testing a memory system comprising a memory device and an electronic device is introduced. The method includes steps of supplying an input signal to an input pad of the memory device; controlling a mode selecting circuit of the memory device to operate the memory device in a first test mode to generate a first output signal; controlling the mode selecting circuit of the memory device to operate the memory device in a second test mode to generate a second output signal; and comparing the first output signal and the second output signal to generate a test result. Loading from a transceiver of the memory interface and the electronic device are included in the first test mode, and the loading of the transceiver of the memory interface and the electronic device are excluded in the second test mode.

In accordance with the above embodiments, a technique for testing a memory system including a SoC device and a memory device connected via embedded pins is introduced. The testing technique uses a mode selecting circuit and the built-in transmitter and receiver of the memory device for testing. The memory system may be sequentially set in the first test mode and the second test mode to generate a first output signal and a second output signal. The first output signal generated in the first test mode may be compared with the second output signal in the second test mode to generate a test result. In this way, the testing technique may check whether there is any degradation after passing transmitters, receivers, pin interface between the SoC device and the memory device. Since the built-in transmitter and a receiver in the memory interface of the memory device are included in the memory device by default, no additional loading caused by DfT circuit, ballouts or direct probing is introduced during testing the memory system. As a result, the testing result is more accurate, and the power consumption and cost for testing is reduced. Furthermore, since no additional loading is introduced, the testing of the memory system does not affect normal operation mode of the memory system. The testing result output by the testing technique may also be used to adjust operations of other circuits and/or to set parameters of other circuits in the memory system.

### BRIEF DESCRIPTION OF THE DRAWINGS

FIG. 1 is a schematic diagram of a memory system comprising an external device, a memory device and a testing device in accordance with some embodiments.

FIG. 2A illustrates a test path of a memory system in a first test mode in accordance with some embodiments.

FIG. 2B illustrates a test path of a memory system in a second test mode in accordance with some embodiments.

FIG. 3 is a schematic diagram of a memory system comprising an external device and a memory device in accordance with some embodiments.

FIG. 4A illustrates a test path of a memory system in a first test mode in accordance with some embodiments.

FIG. 4B illustrates a test path of a memory system in a second test mode in accordance with some embodiments.

FIG. 5 is a flowchart diagram of a method for testing a memory system in accordance with some embodiments.

### DESCRIPTION OF THE EMBODIMENTS

References are made in detail to the present preferred embodiments of the invention, examples of which are illustrated in the accompanying drawings. Wherever possible, the same reference numbers are used in the drawings and the description to refer to the same or like parts.

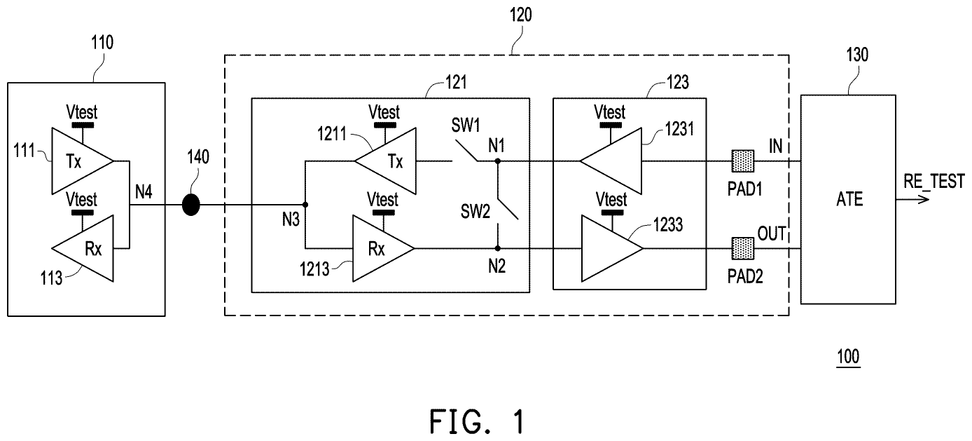

FIG. 1 illustrates a schematic diagram of a memory system 100 including a system-on-chip (SoC) device 110, a memory device 120 and a testing device 130. The SoC device 120 may also referred to as an electronic device, and the testing device 130 may also referred to as an automated testing equipment (ATE). Each of the SoC device 110 and the memory device 120 may be packaged as a chip, and the SoC device 110 may be connected to the memory device 120 via micro-bump (uBump) 140 or embedded pins. In some embodiments, the SoC device 110 and the memory device 120 can be stacked together via uBump 140. In some embodiments, the memory device 120 can include multiple core-dies stacked together using TSV technology.

The SoC device 100 may include a transmitter 111 and a receiver 113, and the SoC device 100 is connected to the memory device 120 via the micro-bump 140. The transmitter 111 of the SoC device 100 may transmit signals or data to the memory device 120, and the receiver 113 of the SoC device 100 may receive signals or data from the memory device 120. Each of the transmitter 111 and the receiver 113 of the SoC device 100 may be supplied with a testing voltage Vtest during a test operation of the memory system 100. During a normal operation of the SoC device 100, the transmitter 111 and the receiver 113 of the SoC device 100 may be supplied with the same or different voltage from the testing voltage Vtest. It is appreciated that the disclosure does not intend to limit the circuit structures of the transmitter 111 and the receiver 113 of the SoC device 100.

The memory device 120 may include an input pad PAD1, an output pad PAD2, a memory interface 121 and a memory test interface 123. The input pad PAD1 is connected to the testing device 130 to receive an input signal IN from the testing device 130, and the output pad PAD2 is connected to the testing device 130 to output an output signal OUT to the testing device 130. The input signal IN and the output signal OUT may be clock signals.

The memory interface 121 may include a transceiver and a mode selecting circuit. The transceiver may include a transmitter 1211 and a receiver 1213, and the mode selecting circuit may include a first switch SW1 and a second switch SW2. The transceiver is configured to transmit or receive data or signals to the SoC device 110 via a connection node N3 and the micro-bump 140. For example, the transmitter 1211 may transmit data and signals to the SoC device 110 via the connection node N3 and the micro-bump 140, and the receiver 1213 may receive data and signals from the SoC device 110 via the connection node N3 and the micro-bump 140. The transmitter 1211 and the receiver 1213 may be supplied with the testing voltage Vtest during a test mode of the memory device 120. During a normal operation mode of the memory device 120, a supply voltage that may be same or different from the testing voltage Vtest can be supplied to the transmitter 1211 and the receiver 1213 of the memory interface 121.

The first switch SW1 of the mode selecting circuit may be connected between a connection node N1 and the transmitter 1211 of the memory interface 121, and is configured to control an electrical connection between the connection node N1 and the transmitter 1211. The second switch SW2 of the mode selecting circuit may be connected between the connection node N1 and a second connection node N2 of the memory interface 121, and is configured to control an electrical connection between the connection node N1 and the connection node N2. The connection node N2 is connected to the receiver 1213 of the memory interface 121.

The first switch SW1 and the second switch SW2 are configured to set a test mode for the memory system 100. For example, when the first switch SW1 is turned on and the second switch SW2 is turned off, the memory system 100 operates in a first test mode; and when the first switch SW1 is turned off and the second switch SW2 is turned on, the memory system 100 operates in a second test mode. In some embodiments, the first switch SW1 and the second switch SW2 are controlled by control signals (not shown) that may be provided by the memory device 120 or the testing device 130.

The memory test interface 123 include a receiving circuit 1231 and a transmitting circuit 1233 being connected between the memory interface 121 and the testing device 130. The receiving circuit 1231 of the memory test interface 123 may receive the data or signals from the testing device 130 via the input pad PAD1, and output data or signals to the connection node N1 of the memory interface 121. The transmitting circuit 1233 may receive data or signals from the memory interface 121 via the connection node N2, and output data or signals to the testing device 130 via the output pad PAD2.

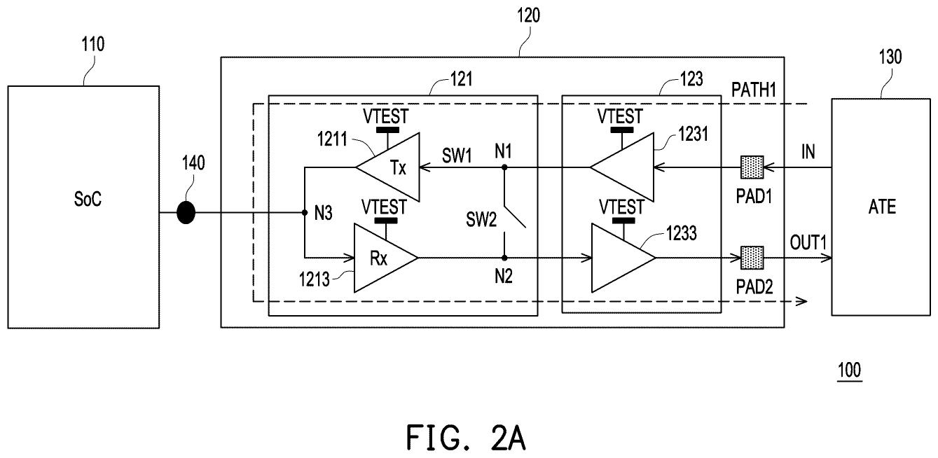

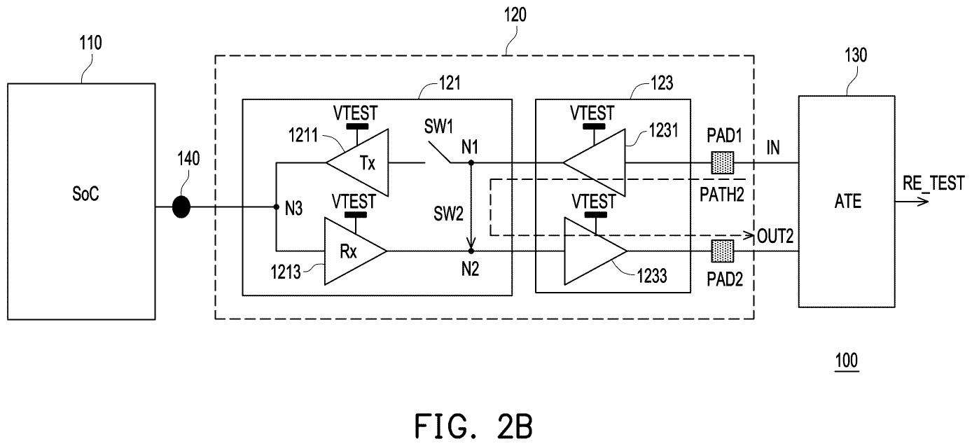

FIG. 2A illustrates a test path PATH1 of the memory system 100 in a first test mode in accordance with some embodiments. Same elements of the memory system 100 in FIG. 2A and FIG. 1 are illustrated with same reference numbers. The memory system 100 operates in the first test mode when the first switch SW1 is turned on and the second switch SW2 is turned off. The first switch SW1 is turned on to electrically connect the connection node N1 to the transmitter 1211 of the memory interface 121, and the second switch SW2 is turned off to electrically disconnect the connection node N1 from the connection node N2. The test path PATH1 that includes the input pad PAD1, the receiving circuit 1231, the connection node N1, the first switch SW1, the transmitter 1211, the connection node N3, the receiver 1213, the connection node N2, the transmitting circuit 1233 and the output pad PAD2 is formed in the first test mode. The test path PATH1 may represent loadings of the receiving circuit 1231 and the transmitting circuit 1233 of the test memory interface 123, loadings of the transmitter 1211 and the receiver 1213 of the memory interface 121 and loadings of the SoC device 110. When the input signal IN is supplied by the testing device 130 to the input pad PAD1 of the memory device 120, the input signal IN flows through the test path PATH1 to generate a first output signal OUT1 at the output pad PAD2 of the memory device 120. The first output signal OUT1 is provided to the testing device 130.

FIG. 2B illustrates a test path PATH2 of the memory system 100 in a second test mode in accordance with some embodiments. Same elements of the memory system 100 in FIG. 2B and FIG. 1 are illustrated with same reference numbers. The memory system 100 operates in the second test mode when the first switch SW1 is turned off and the second switch SW2 is turned on. The first switch SW1 is turned off to electrically disconnect the connection node N1 from the transmitter 1211 of the memory interface 121, and the second switch SW2 is turned on to electrically connect the connection node N1 to the connection node N2. The test path PATH2 that includes the input pad PAD1, the receiving circuit 1231, the connection node N1, the connection node N2, the transmitting circuit 1233 and the output pad PAD2 is formed during the second test mode. The test path PATH2 may represent loadings of the receiving circuit 1231 and the transmitting circuit 1233 of the test memory interface 123. The test path PATH2 does not represent loadings of the transmitter 1211 and the receiver 1213 of the memory interface 121 and loadings of the SoC device 110. When the input signal IN is supplied by the testing device 130 to the input pad PAD1 of the memory device 120, the input signal IN flows through the test path PATH2 to generate a second output signal OUT2 at the output pad PAD2 of the memory device 120. The second output signal OUT2 is provided to the testing device 130.

In some embodiments, the memory system 100 is set to sequentially operate in the first test mode and the second operation mode to generate the first output signal OUT1 and the second output signal OUT2. For example, the mode selecting circuit turns on the first switch SW1 and turn off the second switch SW2 to operate the memory system 100 in the first test mode. Next, the mode selecting circuit may turn off the first switch SW1 and turn on the second switch SW2 to operate the memory system 100 in the second test mode. In some embodiments, the input signal IN, the first output signal OUT1 and the second output signal OUT2 are clock signals.

The testing device 130 may receive the first output signal OUT1 and the second output signal OUT2, and is configured to compare the first output signal OUT1 and the second output signal OUT2 to generate a test result RS_TEST. In some embodiments, the testing device 130 may compare a data valid window (DVW) of the first output signal OUT1 and the DVW of the second output signal OUT2 to generate the test result RS_TEST. For example, the testing device 130 may measure the DVWs of the first output signal OUT1 and the second output signal OUT2, and then compare the DVW of the first output signal OUT1 to the DVW of the second output signal OUT2 to generate the test result RS_TEST. The loadings of the SoC device, the loadings of the transmitter and receiver of the memory interface, and the loadings of the receiving circuit and the transmitting circuit of the memory test interface may be included and represented in the first output signal OUT1; while the loadings of the SoC device and the loadings of the transmitter and receiver of the memory interface may be excluded and not represented in the second output signal OUT2. By comparing the first output signal OUT1 and the second output signal OUT2, the testing device 130 may determine whether there is any degradation in the transmitters, receivers, and interfaces between the SoC circuit and the memory device. In this way, the performance of the memory system may be monitored using the built-in transmitter and receiver of the memory interface (i.e., memory interface 121) of the memory device (i.e., memory device 120). Further, the testing of memory system may be performed without additional loading caused by designs of DfT circuits and/or ballouts package and probing methods.

Additionally, the test result may also be used to set parameters or operating conditions of other circuits and/or devices in the memory system 100. For example, the test result may be used to adjust driver strength of the transmitter 1211 and/or receiver 1213 of the memory device 120. The test result may also be used to adjust the internal falling timing and rising timing of the receiver 1213 of the memory device 120.

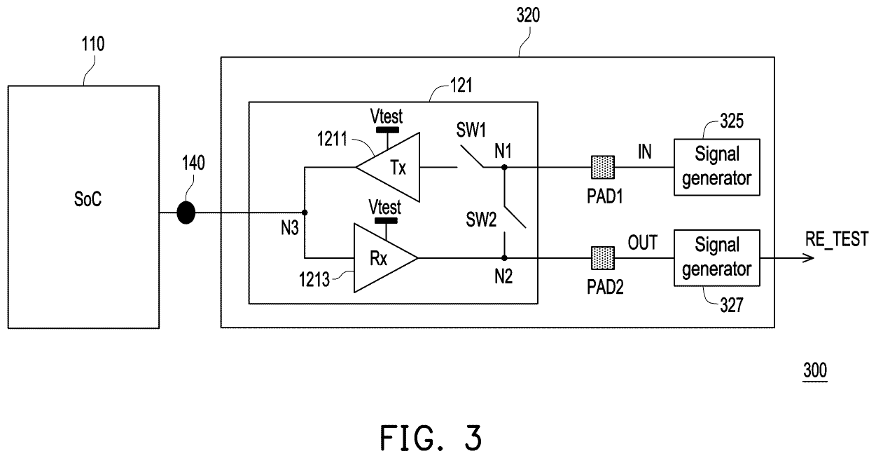

FIG. 3 is a schematic diagram of a memory system 300 including a SoC device 110 and a memory device 320 in accordance with some embodiments. The same elements of the memory system 200 shown in FIG. 3 and the memory system 100 shown in FIG. 1 are illustrated with same reference numbers. A difference between the memory system 300 in FIG. 3 and the memory system 100 in FIG. 1 is that the memory system 300 includes a signal generator 325 and a signal comparator 327. Another difference between the memory system 300 in FIG. 3 and the memory system 100 in FIG. 1 is that the memory system 300 does not include the memory test interface 123 as the memory system 100.

In FIG. 3, the signal generator 325 is connected to the input pad PAD1, and is configured to generate and provide the input signal IN to the input pad PAD1. In other words, the input signal IN is generated by an internal signal generator 325 of the memory device 320, rather than being provided from an external testing device. The signal generator 325 may be a clock generator that is configured to generate a clock signal which serves as the input signal. The signal comparator 327 is connected to the output pad PAD2, and is configured to receive the output signals OUT from the output pad PAD2 of the memory device 320. The signal comparator 327 may compare the output signals OUT obtained in different test modes to generate a test result RE_TEST. The signal comparator 327 may output the test result RE_TEST to other circuits in the system 300. For example, the signal comparator 327 may provide the transmitter (i.e., transmitter 1211) of the memory device 320 to adjust operations or parameters of the transmitter.

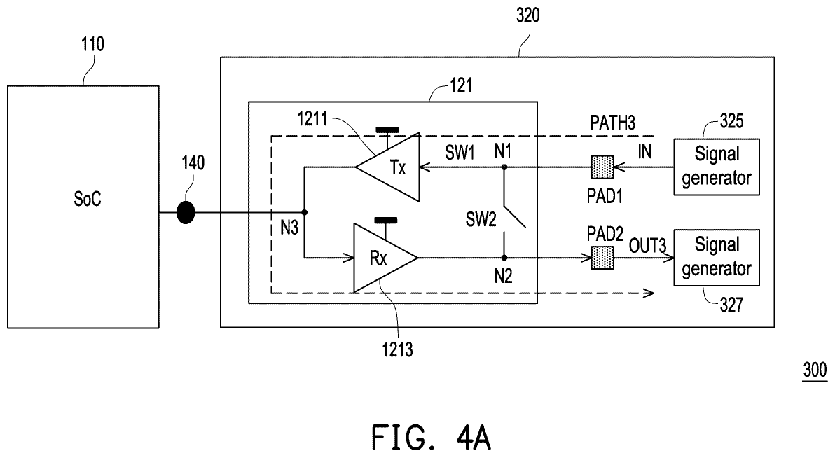

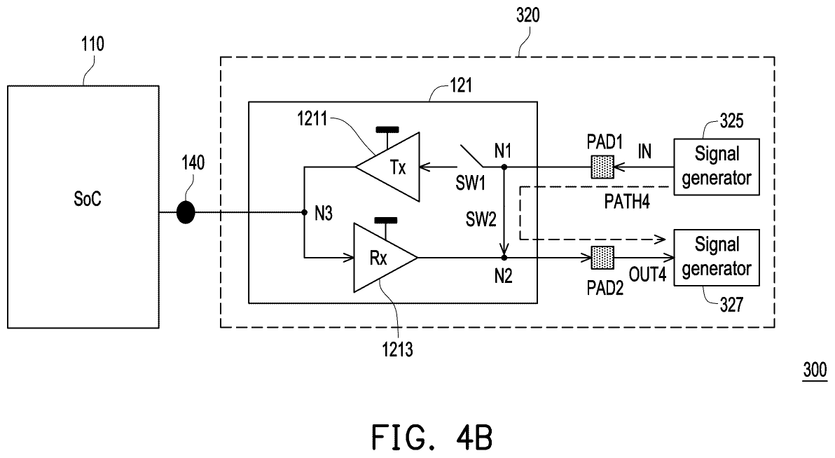

FIG. 4A illustrates a test path PATH3 of the memory system 300 in a first test mode in accordance with some embodiments. Same elements of the memory system 300 in FIG. 4A and FIG. 3 are illustrated with same reference numbers. The memory system 300 operates in the first test mode when the first switch SW1 is turned on and the second switch SW2 is turned off. The test path PATH3 that includes the input pad PAD1, the connection node N1, the first switch SW1, the transmitter 1211, the connection node N3, the receiver 1213, the connection node N2, the output pad PAD2 is formed in the first test mode. The test path PATH3 may represent loadings of the transmitter 1211 and the receiver 1213 of the memory interface 121 and loadings of the SoC device 110. When the input signal IN is supplied by the signal generator 325 to the input pad PAD1 of the memory device 320, the input signal IN flows through the test path PATH3 to generate a third output signal OUT3 at the output pad PAD2 of the memory device 320. The third output signal OUT3 is provided to the signal comparator 327.

FIG. 4B illustrates a test path PATH4 of the memory system 300 in a second test mode in accordance with some embodiments. Same elements of the memory system 300 in FIG. 4B and FIG. 3 are illustrated with same reference numbers. The memory system 300 operates in the second test mode when the first switch SW1 is turned off and the second switch SW2 is turned on. The test path PATH4 that includes the input pad PAD1, the connection node N1, the connection node N2 and the output pad PAD2 is formed in the second test mode. The test path PATH4 may represent loadings of electrical path from the input pad PAD1 to the output pad PAD2. The test path PATH4 does not represent loadings of the transmitter 1211 and the receiver 1213 of the memory interface 121 and loadings of the SoC device 110. When the input signal IN is supplied by the signal generator 325 to the input pad PAD1 of the memory device 320, the input signal IN flows through the test path PATH4 to generate a fourth output signal OUT4 at the output pad PAD2 of the memory device 320. The fourth output signal OUT4 is provided to the signal comparator 327.

In some embodiments, the memory system 300 is set to sequentially operate in the first test mode and the second operation mode to generate the third output signal OUT3 and the fourth output signal OUT4. For example, the mode selecting circuit turns on the first switch SW1 and turn off the second switch SW2 to operate the memory system 300 in the first test mode. Next, the mode selecting circuit may turn off the first switch SW1 and turn on the second switch SW2 to operate the memory system 300 in the second test mode. In some embodiments, the input signal IN, the third output signal OUT3 and the fourth output signal OUT4 are clock signals.

The signal generator 327 may receive the third output signal OUT3 and the fourth output signal OUT4, and is configured to compare the third output signal OUT3 and the fourth output signal OUT4 to generate the test result RE_TEST. In some embodiments, the signal comparator 327 may compare a data valid window (DVW) of the third output signal OUT3 and the DVW of the fourth output signal OUT4 to generate the test result RE_TEST. For example, the signal generator 327 may measure the DVWs of the third output signal OUT3 and the fourth output signal OUT4, and then compare the DVW of the third output signal OUT3 to the DVW of the fourth output signal OUT4 to generate the test result. The loadings of the SoC device, the loadings of the transmitter and receiver of the memory interface may be included and represented in the third output signal OUT3; while the loadings of the SoC device and the loadings of the transmitter and receiver of the memory interface may be excluded and not represented in the fourth output signal OUT4. By comparing the third output signal OUT3 and the fourth output signal OUT4, the signal generator 327 may determine whether there is any degradation in the transmitters, receivers, and interfaces between the SoC circuit and the memory device. In this way, the performance of the memory system may be monitored using the built-in transmitter and receiver of the memory interface (i.e., memory interface 121) of the memory device (i.e., memory device 320). Further, the testing of memory system may be performed without additional loading caused by designs of DfT circuits and/or ballouts package and probing methods.

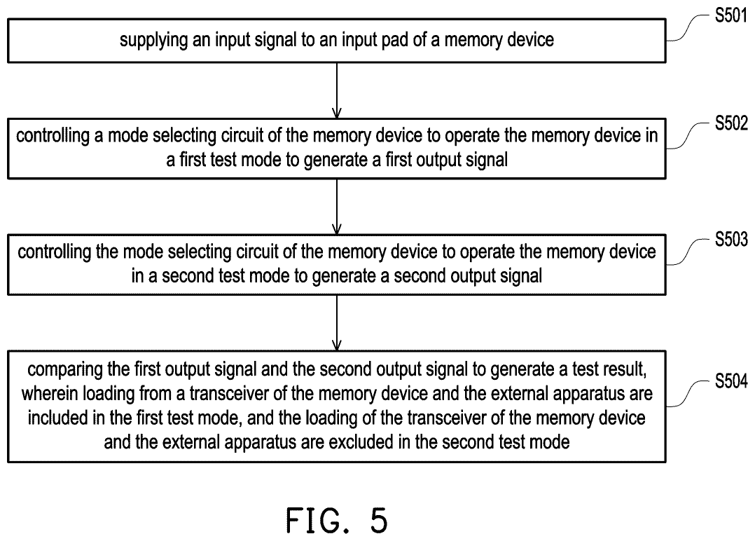

FIG. 5 is a flowchart diagram of a method for testing a memory device in accordance with some embodiments. In block S501, an input signal is supplied to an input pad of a memory device. In block S502, a mode selecting circuit of the memory device is controlled to operate the memory device in a first test mode. A first output signal is generated and outputted to an output pad of the memory device in the first test mode. In block 503, the mode selecting circuit of the memory device is controlled to operate the memory device in a second test mode. A second output signal is generated and outputted to an output pad of the memory device in the second test mode. In block 504, the first output signal is compared with the second output signal to generate a test result. The loading from a transceiver of the memory device and the external device (ex. SoC device) are included in the first test mode, and the loading of the transceiver of the memory device and the external device are excluded in the second test mode.

In accordance with the above embodiments, a mode selecting circuit and the built-in transmitter and receiver of the memory device may be utilized for testing the memory system. The memory system may be sequentially set in the first test mode and the second test mode to generate a first output signal and a second output signal. The first output signal generated in the first test mode may be compared with the second output signal in the second test mode to generate a test result. Since the built-in transmitter and a receiver in the memory interface of the memory device are included in the memory device by default, no additional loading caused by DfT circuit, ballouts or direct probing is introduced during testing the memory system. As a result, the power consumption and cost for testing is reduced, and the testing of the memory system does not affect normal operation mode (ex. normal user mode operation) of the memory system. The testing result may be used to adjust operations of other circuits and/or to set parameters of other circuits in the memory system.

Therefore, the present disclosure provides a green technology by reducing power consumption of the memory system. Also, according to the present disclosure, it is easier to realize the consumers'demand for miniaturization of the memory system. Therefore, the production cost and energy consumption of manufacturing a single IC are reduced, and the production energy consumption of subsequent packaging is also reduced, thereby reducing carbon emissions in the process of producing the memory system.

The memory device of the memory system can be DRAM, non-volatile memory, or a combination thereof. Moreover, the present invention is particularly advantageous for 3D IC applications, such as High Bandwidth Memory (HBM) and other types of stacked memory products. By incorporating built-in transmitters and receivers for testing without additional loading from DfT circuits or probing methods, the invention significantly reduces power consumption and production costs. This results in more efficient and compact memory systems, which are crucial for meeting the growing demands for high-performance, energy-efficient 3D IC solutions.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory system, comprising:
an electronic device;
a memory device, comprising:
an input pad, receiving an input signal;
an output pad, outputting a first output signal in a first test mode and outputting a second output signal in a second test mode; and
a memory interface, wherein the memory interface comprises:
a transceiver, communicating the electronic device; and
a mode selecting circuit, selecting the first test mode or the second test mode, wherein loading from the transceiver of the memory interface and the electronic device are included in the first test mode, and the loading from the transceiver of the memory interface and the electronic device are excluded in the second test mode; and
a testing device, connected to the memory device, comparing the first output signal and the second output signal to generate a test result.

2. The memory system of claim 1, wherein the transceiver comprises:
a transmitter, transmitting signals to the electronic device; and
a receiver, receiving signals from the electronic device.

3. The memory system of claim 2, wherein the mode selecting circuit comprises:
a first switch, connected between a first connection node and the transmitter of the memory interface; and
a second switch, connected between the first connection node and a second connection node, wherein the second connection node is connected to the receiver of the memory interface.

4. The memory system of claim 3, wherein
the first switch is turned on and the second switch is turned off in the first test mode, and
the first switch is turned off and the second switch is turned on in the second test mode.

5. The memory system of claim 3, further comprising:
a memory test interface, connecting between the memory interface and the testing device, wherein the memory test interface comprises:
a receiving circuit, connected between the input pad of the memory device and the first connection node;
a transmitting circuit, connected between the second connection node and the output pad of the memory device.

6. The memory system of claim 5, wherein
the input signal, the first output signal and the second output signal are clock signals.

7. The memory system of claim 1, wherein
the testing device is configured to compare a data valid window of the first output signal to a data valid window of the second output signal to generate the test result.

8. The memory system of claim 1, wherein
the electronic device is a system on chip (SoC) device, and
the testing device is an automated test equipment (ATE).

9. A memory system, comprising:
an electronic device;
a memory device, comprising:
an input pad, receiving an input signal;
an output pad, outputting a first output signal in a first test mode and outputting a second output signal in a second test mode;
a memory interface, wherein the memory interface comprises:
a transceiver, communicating the electronic device; and
a mode selecting circuit, selecting the first test mode or the second test mode, wherein loading from the transceiver of the memory interface and the electronic device are included in the first test mode, and the loading of the transceiver of the memory interface and the electronic device are excluded in the second test mode; and
a signal comparator, comparing the first output signal and the second output signal to generate a test result.

10. The memory system of claim 9, wherein the transceiver comprises:
a transmitter, transmitting signals to the electronic device; and
a receiver, receiving signals from the electronic device.

11. The memory system of claim 10, wherein the mode selecting circuit comprises:
a first switch, connected between a first connection node and the transmitter of the memory interface; and
a second switch, connected between the first connection node and a second connection node, wherein the second connection node is connected to the receiver of the memory interface.

12. The memory system of claim 11, wherein
the first switch is turned on and the second switch is turned off in the first test mode, and
the first switch is turned off and the second switch is turned on in the second test mode.

13. The memory system of claim 11, wherein the memory device further comprises:
a signal generator, connected to the input pad of the memory device, generating the input signal and supplying the input signal to the input pad of the memory device.

14. The memory system of claim 9, wherein
the signal comparator is configured to compare a data valid window of the first output signal to a data valid window of the second output signal to generate the test result.

15. The memory system of claim 9, wherein
the input signal, the first output signal and the second output signal are clock signals, and
the electronic device is a system on chip (SoC) device.

16. A method of testing a memory device connected between an external device and a testing device, the method comprising:
supplying an input signal to an input pad of the memory device;
controlling a mode selecting circuit of the memory device to operate the memory device in a first test mode to generate a first output signal;
controlling the mode selecting circuit of the memory device to operate the memory device in a second test mode to generate a second output signal;
comparing the first output signal and the second output signal to generate a test result,
wherein loading from a transceiver of the memory interface and the electronic device are included in the first test mode, and the loading of the transceiver of the memory interface and the electronic device are excluded in the second test mode.

17. The method of claim 16, wherein controlling the mode selecting circuit comprises:
turning on a first switch of the mode selecting circuit and turning off a second switch in the first test mode; and
turning off the first switch of the mode selecting circuit and turning on the second switch in the second test mode.

18. The method of claim 16, wherein supplying the input signal to the input pad of the memory device comprises:
supplying the input signal from the testing device to the input pad of the memory device.

19. The method of claim 16, wherein supplying the input signal to the input pad of the memory device comprises:
generating, by a signal generator of the memory device, the input signal; and
supplying the input signal generated by the signal generator to the input pad of the memory device.

20. The method of claim 16, wherein comparing the first output signal and the second output signal to generate the test result comprises:
comparing a data valid window of the first output signal to a data valid window of the second output signal to generate the test result.
